(19) United States
(12) Patent Application Publication
(10) Pub. No.: US 2025/0142958 A1
(43) Pub. Date: May 1, 2025

(54) SEMICONDUCTOR STRUCTURE AND FABRICATION METHOD THEREOF

(71) Applicant: UNITED MICROELECTRONICS CORP., Hsin-Chu City (TW)

(72) Inventors: Tai-Cheng Hou, Tainan City (TW); Da-Jun Lin, Kaohsiung City (TW); Bin-Siang Tsai, Changhua County (TW); Fu-Yu Tsai, Tainan City (TW)

(73) Assignee: UNITED MICROELECTRONICS CORP., Hsin-Chu City (TW)

(21) Appl. No.: 18/534,754

(22) Filed: Dec. 11, 2023

(30) Foreign Application Priority Data
Oct. 27, 2023 (TW) 112141168

(51) Int. Cl. H01L 27/12; H01L 21/02; H01L 21/768; H01L 23/522; H01L 23/532; H01L 29/66; H01L 29/792

(52) U.S. Cl. CPC H10D 86/201; H01L 21/02362; H01L 21/76805; H01L 23/5226; H01L 23/53214; H01L 23/53228; H10D 30/0413; H10D 30/69

(57) ABSTRACT

A semiconductor structure includes a SOI substrate having a device layer and a buried oxide layer contiguous with the device layer; a transistor disposed on the device layer; a dielectric layer surrounding the transistor; an interconnect structure disposed on the dielectric layer and electrically connected to a gate of the transistor; a charge trapping layer contiguous with the buried oxide layer; a capping layer contiguous with the charge trapping layer; and a conductive via penetrating through the capping layer, the charge trapping layer, the buried oxide layer, the device layer, and the dielectric layer. The conductive via is electrically connected to the interconnect structure.

### BACKGROUND OF THE INVENTION

### 1. Field of the Invention

The present invention relates to the field of semiconductor technology, and in particular, to an improved semiconductor structure and a manufacturing method thereof.

### 2. Description of the Prior Art

Semiconductor-on-insulator (SOI) technology is particularly appealing for high frequency applications such as radio frequency (RF) communication circuits and three-dimensional integrated circuit (3D IC) chips.

A SOI structure typically includes a substrate layer, an insulator layer, and an active layer. The substrate layer is typically a semiconductor material such as silicon. The insulator layer is a dielectric which is often silicon dioxide formed through the oxidation of the substrate layer in situations where the substrate layer is silicon. The active layer includes an active device layer and a metallization or metal interconnect layer. The circuitry may include metal wiring (e.g. in the metal interconnect layer); passive devices such as resistors, capacitors, and inductors; and active devices such as a transistor (e.g. in the active device layer).

In the application of three-dimensional integrated circuit chips, the breakdown voltage (BVD) of the top wafer with input-output NMOS (IO-NMOS) circuitry is comparable to the breakdown voltage of the bottom wafer before wafer bonding. However, the results of the wafer acceptance testing (WAT) show that after the wafers were bonded, the breakdown voltage of the top wafer has approximately 0.8V shift.

### SUMMARY OF THE INVENTION

It is one object of the present invention to provide an improved semiconductor structure and a manufacturing method thereof to solve the above-mentioned shortcomings or deficiencies of the prior art.

One aspect of the invention provides a semiconductor structure including a silicon-on-insulator (SOI) substrate comprising a device layer and a buried oxide layer being contiguous with the device layer; at least one transistor disposed on the device layer; a dielectric layer surrounding the at least one transistor; an interconnect structure disposed on the dielectric layer and being electrically connected to a gate of the at least one transistor; a charge trapping layer being contiguous with the buried oxide layer; a capping layer being contiguous with the charge trapping layer; and a conductive via penetrating through the capping layer, the charge trapping layer, the buried oxide layer, the device layer, and the dielectric layer. The conductive via is electrically connected to the interconnect structure and is further electrically connected to the at least one transistor through the interconnect structure.

According to some embodiments, the at least one transistor is a fully-depleted silicon-on-insulator metal-oxide-semiconductor transistor.

According to some embodiments, the charge trapping layer comprises a phosphosilicate glass (PSG) layer or a borosilicate glasses (BSG) layer.

According to some embodiments, the charge trapping layer has a thickness of about 80-120 angstroms.

According to some embodiments, the capping layer comprises a silicon nitride layer.

According to some embodiments, the conductive via comprises copper.

According to some embodiments, the dielectric layer comprises an undoped silicate glass (USG) layer.

According to some embodiments, the semiconductor structure further includes an insulating layer being contiguous with the capping layer; a passivation layer being contiguous with the insulating layer; and a metal wiring layer disposed in the insulating layer and the passivation layer.

According to some embodiments, the insulating layer comprises a silicon oxide layer and the passivation layer comprises a silicon nitride layer.

According to some embodiments, the metal wiring layer is an aluminum wiring layer.

Another aspect of the invention provides a method for forming a semiconductor structure. A silicon-on-insulator (SOI) substrate having a device layer and a buried oxide layer being contiguous with the device layer is provided. At least one transistor is formed on the device layer. A dielectric layer surrounding the at least one transistor is formed. An interconnect structure is formed on the dielectric layer. The interconnect structure is electrically connected to a gate of the at least one transistor. A charge trapping layer that is contiguous with the buried oxide layer is formed. A capping layer that is contiguous with the charge trapping layer is formed. A conductive via is formed. The conductive via penetrates through the capping layer, the charge trapping layer, the buried oxide layer, the device layer, and the dielectric layer. The conductive via is electrically connected to the interconnect structure and is further electrically connected to the at least one transistor through the interconnect structure.

According to some embodiments, the at least one transistor is a fully-depleted silicon-on-insulator metal-oxide-semiconductor transistor.

According to some embodiments, the charge trapping layer comprises a phosphosilicate glass (PSG) layer or a borosilicate glasses (BSG) layer.

According to some embodiments, the charge trapping layer has a thickness of about 80-120 angstroms.

According to some embodiments, the capping layer comprises a silicon nitride layer.

According to some embodiments, the conductive via comprises copper.

According to some embodiments, the dielectric layer comprises an undoped silicate glass (USG) layer.

According to some embodiments, the method further includes the steps of forming an insulating layer contiguous with the capping layer; forming a passivation layer contiguous with the insulating layer; and forming a metal wiring layer in the insulating layer and the passivation layer.

According to some embodiments, the insulating layer comprises a silicon oxide layer and the passivation layer comprises a silicon nitride layer.

According to some embodiments, the metal wiring layer is an aluminum wiring layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic diagrams of a method of forming a semiconductor structure according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

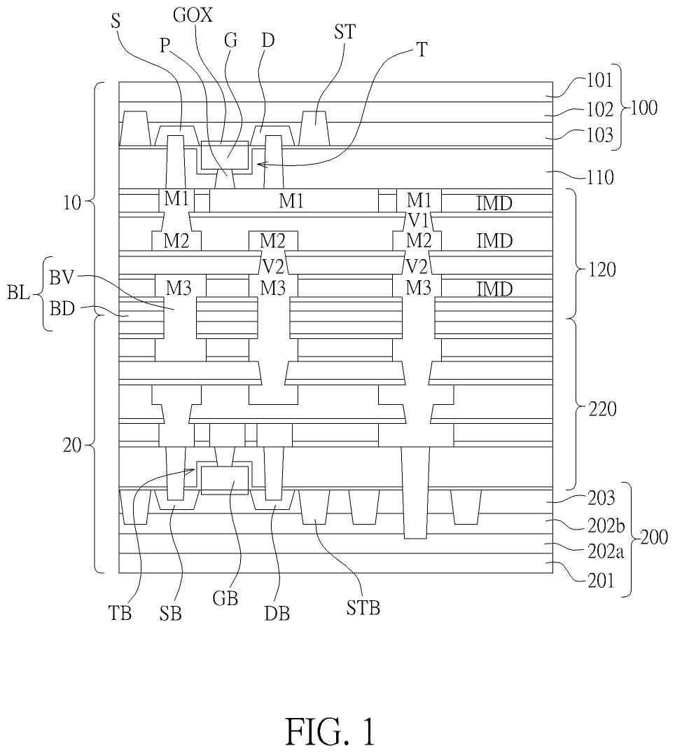

Please refer to FIG. 1 to FIG. 4, which are schematic diagrams of a method of forming a semiconductor structure 1 according to an embodiment of the present invention. As shown in FIG. 1, a first wafer 10 and a second wafer 20 are provided. The bonding layers BL of the first wafer 10 and the second wafer 20 may be bonded to each other by using, for example, plasma activated bonding (PAB) technology. According to an embodiment of the present invention, for example, the bonding layer BL may comprise a bonding via BV and a bonding dielectric layer BD, but is not limited thereto. According to an embodiment of the present invention, for example, the bonding via BV may comprise a copper through hole, and the bonding dielectric layer BD may comprise silicon dioxide or silicon nitride, but is not limited thereto.

According to an embodiment of the present invention, the first wafer 10 may comprise a silicon-on-insulator (SOI) substrate 100. For example, the SOI substrate 100 may comprise a base layer 101, a buried oxide layer 102 that is in contiguous with the base layer 101, and a device layer 103 that is in contiguous with the buried oxide layer 102. A dielectric layer 110 may be formed on the device layer 103. According to an embodiment of the present invention, the dielectric layer 110 may comprise an undoped silicate glass (USG) layer, but is not limited thereto. According to an embodiment of the present invention, an interconnect structure 120 may be formed on the dielectric layer 110. For example, the interconnect structure 120 may comprise metal conductor layers M1-M3, via layers V1 and V2, and an inter-metal dielectric layer IMD.

According to an embodiment of the present invention, a circuit element, such as a transistor T, may be formed in the device layer 103 and the dielectric layer 110. For example, the transistor T may be a MOS transistor in an input-output (I/O) NMOS circuit. According to an embodiment of the present invention, for example, the transistor T may comprise a gate G formed on the device layer 103 and surrounded by a dielectric layer 110, a gate oxide layer GOX under the gate G, a source doping region S formed in the device layer 103, and a drain doping region D formed in the device layer 103. According to an embodiment of the present invention, for example, the gate G may be a polysilicon gate or a metal gate. The transistor T may be electrically isolated by the shallow trench insulation (STI) structure ST formed in the device layer 103.

According to an embodiment of the present invention, for example, the transistor T may be an NMOS transistor, and the source doping region S and the drain doping region D may be N+ doping regions. According to an embodiment of the present invention, the transistor T may be a fully-depleted silicon-on-insulator metal oxide semiconductor transistor. According to an embodiment of the present invention, the gate G of the transistor T may be electrically connected to the metal conductor layer M1 of the interconnect structure 120 through a contact plug P such as a tungsten plug formed in the dielectric layer 110.

According to an embodiment of the present invention, likewise, the second wafer 20 may comprise a silicon-on-insulator (SOI) substrate 200. For example, the SOI substrate 200 may comprise a base layer 201, a trap rich layer 202a that is contiguous with the base layer 201, a buried oxide layer 202b that is contiguous with the trap rich layer 202a, and a device layer 203 that is contiguous with the buried oxide layer 202b. According to an embodiment of the present invention, for example, the trap-rich layer 202a may comprise amorphous silicon or polycrystalline silicon. A dielectric layer 210 may be formed on the device layer 203. According to an embodiment of the present invention, the dielectric layer 210 may comprise an undoped silicate glass (USG) layer, but is not limited thereto. According to an embodiment of the present invention, an interconnect structure 220 may be formed on the dielectric layer 210. For example, the interconnect structure 220 may comprise a plurality of metal conductor layers, via layers, and inter-metal dielectric layers.

According to an embodiment of the present invention, a circuit element, such as a transistor TB, may be formed in the device layer 203 and the dielectric layer 210. According to an embodiment of the present invention, for example, the transistor TB may comprise a gate GB formed on the device layer 203 and surrounded by a dielectric layer 210, a source doping region SB formed in the device layer 203, and a drain doping region DB formed in the device layer 203. According to an embodiment of the present invention, for example, the gate GB may be a polysilicon gate or a metal gate. The transistor TB may be electrically isolated by the shallow trench insulation structure STB formed in the device layer 203. According to an embodiment of the present invention, the transistor TB may be a fully depleted silicon-on-insulator metal oxide semiconductor transistor.

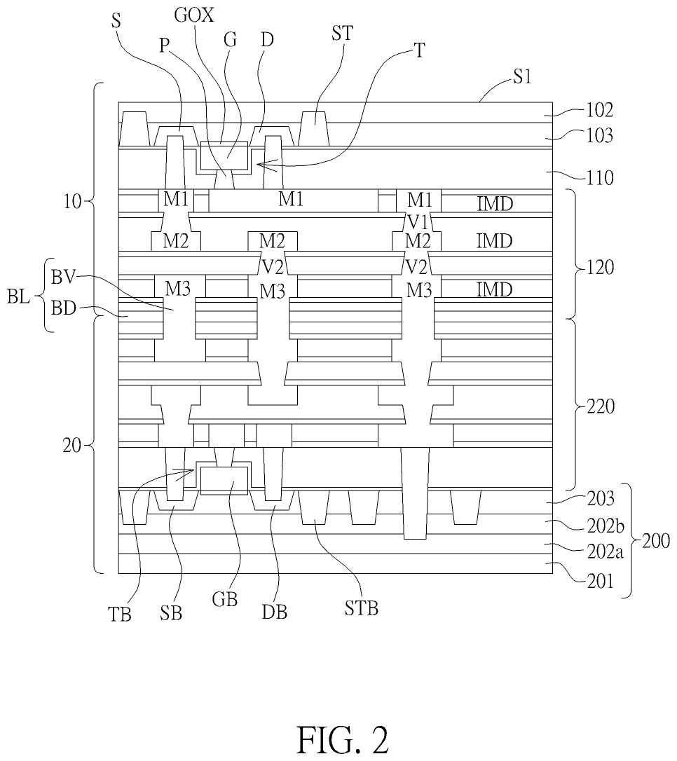

As shown in FIG. 2, next, a polishing process or a tetramethylamine hydroxide (TMAH) etching process may be performed to remove the base layer 101 of the first wafer 10 to expose the surface S1 of the buried oxide layer 102.

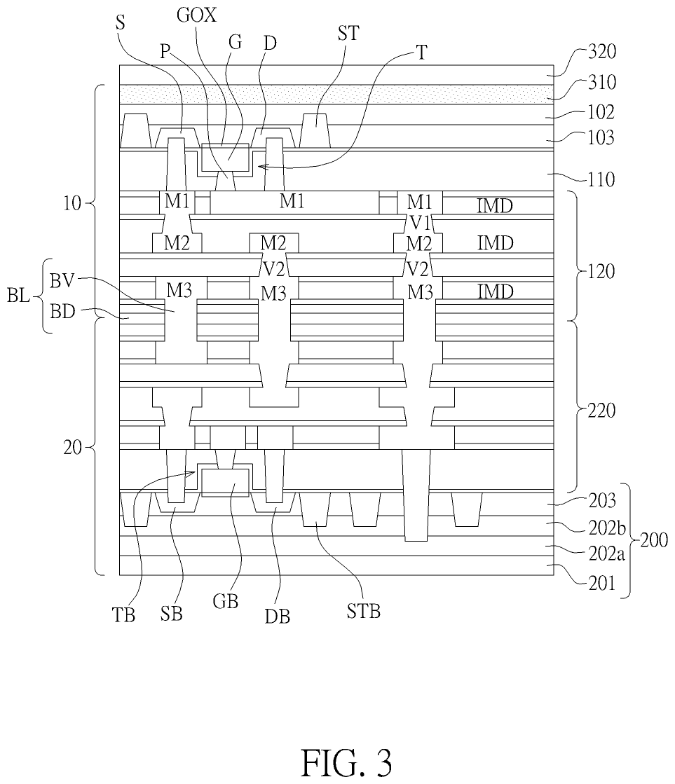

As shown in FIG. 3, a chemical vapor deposition (CVD) process is then performed to form a charge trapping layer 310 that is contiguous with the buried oxide layer 102. According to an embodiment of the present invention, the charge trapping layer 310 comprises a phosphosilicate glass (PSG) layer or a borosilicate glass (BSG) layer. According to an embodiment of the present invention, the thickness of the charge trapping layer 310 is approximately 80-120 angstroms. A chemical vapor deposition process is then performed to form a capping layer 320 that is contiguous with the charge trapping layer 310. According to an embodiment of the present invention, for example, the capping layer 320 may comprise a silicon nitride layer.

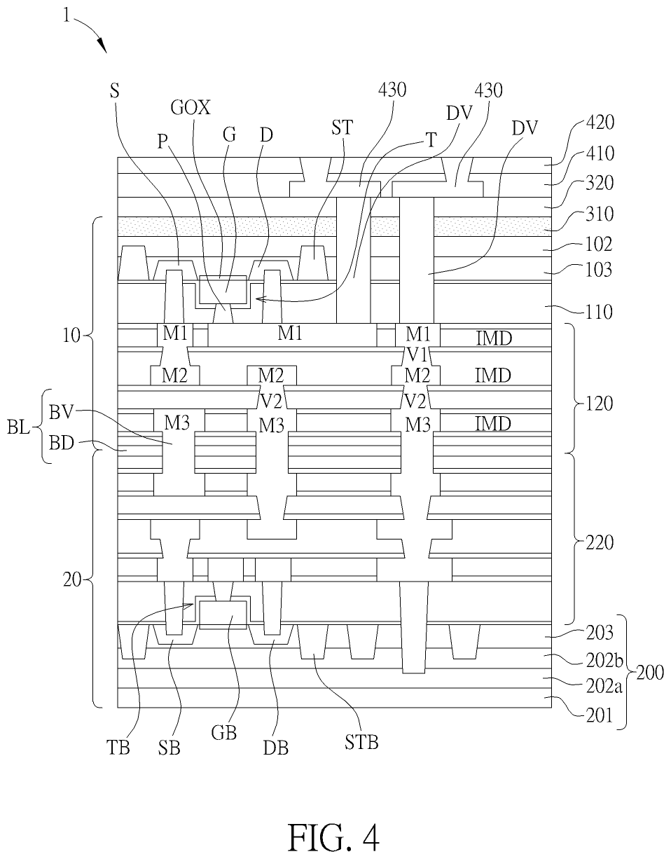

As shown in FIG. 4, a metallization process is then performed to form a conductive via DV that penetrates through the capping layer 320, the charge trapping layer 310, the buried oxide layer 102, the device layer 103 and the dielectric layer 110. The conductive via DV is electrically connected to the metal conductor layer M1 of the interconnect structure 120, and is electrically connected to the transistor T, for example, to the gate G of the transistor T, through the metal conductor layer M1. According to an embodiment of the present invention, the conductive via DV may comprise copper. Subsequently, a chemical vapor deposition process, such as a plasma-enhanced chemical vapor deposition (PECVD) process, may be performed to form the insulating layer 410 that is contiguous with the capping layer 320. A passivation layer 420 that is contiguous with the insulating layer 410 is then formed. According to an embodiment of the present invention, the insulating layer 410 may comprise a silicon oxide layer, and the passivation layer 420 may comprise a silicon nitride layer. Finally, a metallization process is performed to form a metal circuit layer 430 in the insulating layer 410 and the passivation layer 420. According to an embodiment of the present invention, the metal circuit layer 430 may be an aluminum circuit layer.

One advantage of the present invention is that the charge trapping layer 310 formed on the buried oxide layer 102 is used to trap the charges located in the buried oxide layer 102 so that they will not travel along the conductive via DV and interconnect structures 120 to damage the gate oxide layer GOX of the transistor T. The improved semiconductor structure can effectively prevent the breakdown voltage shifting problem of the top wafer after wafer bonding.

Structurally, as shown in FIG. 4, the semiconductor structure 1 of the present invention comprises a silicon-on-insulator substrate 100 comprising a device layer 103 and a buried oxide layer 102 that is contiguous with the device layer 103.

The semiconductor structure 1 of the present invention further comprises at least one transistor T, which is disposed on the device layer 103. According to an embodiment of the present invention, the at least one transistor T is a fully-depleted silicon-on-insulator metal oxide semiconductor transistor.

The semiconductor structure 1 of the present invention further comprises a dielectric layer 110 surrounding at least one transistor T. According to an embodiment of the present invention, the dielectric layer comprises an undoped silicate glass layer.

The semiconductor structure 1 of the present invention further comprises an interconnect structure 120 disposed on the dielectric layer 110 and electrically connected to the gate G of at least one transistor T.

The semiconductor structure 1 of the present invention further comprises a charge trapping layer 310 that is contiguous with the buried oxide layer 102. The buried oxide layer 102 is sandwiched between the device layer 103 and the charge trapping layer 310. According to an embodiment of the present invention, the charge trapping layer 310 may comprise a phosphosilicate glass (PSG) layer or a borosilicate glass (BSG) layer. According to an embodiment of the present invention, the thickness of the charge trapping layer 310 is about 80-120 angstroms.

The semiconductor structure 1 of the present invention further comprises a capping layer 320 that is contiguous with the charge trapping layer 310. According to an embodiment of the present invention, the capping layer 320 may comprise a silicon nitride layer.

The semiconductor structure 1 of the present invention further comprises a conductive via DV that penetrates through the capping layer 320, the charge trapping layer 310, the buried oxide layer 102, the device layer 103, and the dielectric layer 110. According to an embodiment of the present invention, the conductive via DV is electrically connected to the metal conductor layer M1 of the interconnect structure 120. According to an embodiment of the present invention, the conductive via DV comprises copper.

The semiconductor structure 1 of the present invention further comprises an insulating layer 410 that is contiguous with the capping layer 320; a passivation layer 420 that is contiguous with the insulating layer 410; and a metal circuit layer 430 disposed in the insulating layer 410 and the passivation layer 420. According to an embodiment of the present invention, the insulating layer 410 may comprise a silicon oxide layer, and the passivation layer 420 may comprise a silicon nitride layer. According to an embodiment of the present invention, the metal circuit layer 430 is an aluminum circuit layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a silicon-on-insulator (SOI) substrate comprising a device layer and a buried oxide layer being contiguous with the device layer;
at least one transistor disposed on the device layer;
a dielectric layer surrounding the at least one transistor;
an interconnect structure disposed on the dielectric layer and being electrically connected to a gate of the at least one transistor;
a charge trapping layer being contiguous with the buried oxide layer;
a capping layer being contiguous with the charge trapping layer; and
a conductive via penetrating through the capping layer, the charge trapping layer, the buried oxide layer, the device layer, and the dielectric layer, wherein the conductive via is electrically connected to the interconnect structure and is further electrically connected to the at least one transistor through the interconnect structure.

2. The semiconductor structure according to claim 1, wherein the at least one transistor is a fully-depleted silicon-on-insulator metal-oxide-semiconductor transistor.

3. The semiconductor structure according to claim 1, wherein the charge trapping layer comprises a phosphosilicate glass (PSG) layer or a borosilicate glasses (BSG) layer.

4. The semiconductor structure according to claim 1, wherein the charge trapping layer has a thickness of about 80-120 angstroms.

5. The semiconductor structure according to claim 1, wherein the capping layer comprises a silicon nitride layer.

6. The semiconductor structure according to claim 1, wherein the conductive via comprises copper.

7. The semiconductor structure according to claim 1, wherein the dielectric layer comprises an undoped silicate glass (USG) layer.

8. The semiconductor structure according to claim 1 further comprising:
an insulating layer being contiguous with the capping layer;
a passivation layer being contiguous with the insulating layer; and
a metal wiring layer disposed in the insulating layer and the passivation layer.

9. The semiconductor structure according to claim 8, wherein the insulating layer comprises a silicon oxide layer and the passivation layer comprises a silicon nitride layer.

10. The semiconductor structure according to claim 8, wherein the metal wiring layer is an aluminum wiring layer.

11. A method for forming a semiconductor structure, comprising:
providing a silicon-on-insulator (SOI) substrate comprising a device layer and a buried oxide layer being contiguous with the device layer;
forming at least one transistor on the device layer;
forming a dielectric layer surrounding the at least one transistor;
forming an interconnect structure on the dielectric layer, wherein the interconnect structure is electrically connected to a gate of the at least one transistor;
forming a charge trapping layer contiguous with the buried oxide layer;
forming a capping layer contiguous with the charge trapping layer; and
forming a conductive via penetrating through the capping layer, the charge trapping layer, the buried oxide layer, the device layer, and the dielectric layer, wherein the conductive via is electrically connected to the interconnect structure and is further electrically connected to the at least one transistor through the interconnect structure.

12. The method according to claim 11, wherein the at least one transistor is a fully-depleted silicon-on-insulator metal-oxide-semiconductor transistor.

13. The method according to claim 11, wherein the charge trapping layer comprises a phosphosilicate glass (PSG) layer or a borosilicate glasses (BSG) layer.

14. The method according to claim 11, wherein the charge trapping layer has a thickness of about 80-120 angstroms.

15. The method according to claim 11, wherein the capping layer comprises a silicon nitride layer.

16. The method according to claim 11, wherein the conductive via comprises copper.

17. The method according to claim 11, wherein the dielectric layer comprises an undoped silicate glass (USG) layer.

18. The method according to claim 11 further comprising:
forming an insulating layer contiguous with the capping layer;
forming a passivation layer contiguous with the insulating layer; and
forming a metal wiring layer in the insulating layer and the passivation layer.

19. The method according to claim 18, wherein the insulating layer comprises a silicon oxide layer and the passivation layer comprises a silicon nitride layer.

20. The method according to claim 18, wherein the metal wiring layer is an aluminum wiring layer.
